(19) United States
(12) Patent Application Publication
(10) Pub. No.: US 2009/0256207 A1
(43) Pub. Date: Oct. 15, 2009

(54) FINFET DEVICES FROM BULK SEMICONDUCTOR AND METHODS FOR MANUFACTURING THE SAME

(75) Inventors: Xiaomeng Chen, Poughkeepsie, NY (US); Bachir Dirahoui, Bedford Hills, NY (US); William K. Henson, Beacon, NY (US); Michael D. Hulvey, Shelburne, VT (US); Amit Kumar, Williston, VT (US); Mahender Kumar, Fishkill, NY (US); Amanda L. Tessier, Poughkeepsie, NY (US); Clement H. Wann, Carmel, NY (US)

Correspondence Address: CANTOR COLBURN LLP - IBM FISHKILL, 20 Church Street, 22nd Floor, Hartford, CT, 06103, US

(73) Assignee: INTERNATIONAL BUSINESS MACHINES CORPORATION, Armonk, NY (US)

(21) Appl. No.: 12/102,333

(22) Filed: Apr. 14, 2008

(51) Int. Cl. H01L 27/088; H01L 21/336

(52) U.S. Cl. 257/365; 438/283; 257/E27.06

(57) ABSTRACT

Disclosed herein is a transistor comprising a first fin having a first gate electrode disposed across the first fin; the gate electrode contacting opposing surfaces of the fin; and a planar oxide layer having a second gate electrode disposed across the planar oxide layer to form a planar metal oxide semiconductor field effect transistor; the first fin and the planar oxide layer being disposed upon a surface of a wafer.

### BACKGROUND

This disclosure relates to finFET devices from bulk semiconductor and to methods for manufacturing the same.

Metal-Oxide-Semiconductor field effect transistor (MOSFET) technology is the dominant electronic device technology in use today. Performance enhancement between generations of devices is generally achieved by reducing the size of the device, resulting in an enhancement in device speed. This is generally referred to as device “scaling”.

Ultra-large-scale integrated (ULSI) circuits generally include a multitude of transistors, such as more than one million transistors and even several million transistors that cooperate to perform various functions for an electronic component. The transistors are generally complementary metal oxide semiconductor field effect transistors (CMOSFETs) that include a gate conductor disposed between a source region and a drain region. The gate conductor is provided over a thin gate oxide material. Generally, the gate conductor can be a metal, a polysilicon, or polysilicon/germanium (SiₓGe₍₁₋ₓ₎) material that controls charge carriers in a channel region between the drain and the source to turn the transistor on and off. The transistors can be N-channel MOSFETs or P-channel MOSFETs.

In bulk semiconductor-type devices, transistors such as MOSFETs, are built on the top surface of a bulk substrate. The substrate is doped to form source and drain regions, and a conductive layer is provided between the source and drain regions. The conductive layer operates as a gate for the transistor; the gate controls current in a channel between the source and the drain regions. As transistors become smaller, the body thickness of the transistor (or thickness of depletion layer below the inversion channel) is scaled down to achieve superior short-channel performance.

As MOSFETs are scaled to channel lengths below 100 nm, conventional MOSFETs suffer from several problems. In particular, interactions between the source and drain of the MOSFET degrade the ability of the gate to control whether the device is on or off. This phenomenon is called the “short-channel effect” or SCE.

In order to reduce SCE, double-gate MOSFET structures have been designed. In a double-gated MOSFET, a second gate is disposed in the device between the source and the drain such that there is a gate on either side of a channel that connects the source and the drain. This allows gate control of the channel from both sides, reducing SCE. Additionally, when the device is turned on using both gates, two conduction (“inversion”) layers are formed, allowing for more current flow. An extension of the double-gate concept is the “surround-gate” or “wraparound-gate” concept, where the gate is placed such that it completely or almost-completely surrounds the channel, providing better gate control. The double gated MOSFET device is often referred to as a finFET device.

FinFET devices have received significant attention because of their advantages related to high drive current and high immunity to short channel effects. The finFET device is able to increase the drive current because the gate surrounds the active region by more than one layer (e.g., the effective gate total width is increased due to the double gate structure).

However, as the miniaturization of semiconductor devices proceeds, patterning narrow, dense active regions has become more challenging. For example, conventional lithographic tools are unable to accurately and precisely define active regions as structures or features with dimensions below 100 nm or 50 nm. It is therefore desirable to have a manufacturing process that affords the patterning of narrow, dense, active regions that can be used for fabricating a finFET device. It is also desirable that the manufacturing process be compatible with existing MOSFET fabrication processes.

### SUMMARY

Disclosed herein is a transistor comprising a first fin having a first gate electrode disposed across the first fin; the gate electrode contacting opposing surfaces of the fin; and a planar oxide layer having a second gate electrode disposed across the planar oxide layer to form a planar metal oxide semiconductor field effect transistor; the first fin and the planar oxide layer being disposed upon a surface of a wafer.

Disclosed herein too is a method comprising disposing a N+ dopant on a portion of a wafer to form a buried oxide layer; disposing an epitaxially deposited silicon layer on the wafer over the buried oxide layer; disposing a pad oxide layer and a silicon nitride mask on the epitaxially deposited silicon layer; the pad oxide layer being disposed beneath the silicon nitride mask; etching a shallow trench in the wafer; the shallow trench extending into the wafer from the nitride mask; laterally etching the wafer; removing a portion of the buried oxide layer from a side of the wafer; creating an empty space in the side of the buried oxide layer; disposing an oxide strap around the wafer to encompass the silicon nitride mask; a portion of the oxide strap being disposed in the space created in the side of the buried oxide layer; removing the buried oxide layer from the wafer; disposing a conformal oxide on the wafer; planarizing the conformal oxide to expose a surface of the pad oxide; disposing a photoresist reactive ion etch mask on the pad oxide; and etching the pad oxide away to create a fin on a surface of the wafer.

Disclosed herein too are article that use the aforementioned transistor and the aforementioned method.

### BRIEF DESCRIPTION OF FIGURES

FIG. 1 is an exemplary perpective view of a simple finFET device;

FIG. 2 is a cross-sectional view of the finFET device taken at section AA′ of the FIG. 1;

FIG. 3A is an exemplary end-on view of the implanting of the N+ dopant;

FIG. 3B is an exemplary side view of the implanting of the N+ dopant in the second region of the wafer, while a resist is disposed on the first region of the wafer;

FIG. 4A is an exemplary end-on view of the disposing of EPI layer;

FIG. 4B is an exemplary side view of the disposing of EPI layer on both the first and the second regions of the wafer;

FIG. 5 is an exemplary depiction of the formation of the STI trench in the wafer;

FIG. 6 is an exemplary depiction of the wafer after the lateral etch, where a portion of the BOX layer is removed;

FIG. 7A is an exemplary depiction of the top view after the disposing of the oxide pillar/strap on the wafer;

FIG. 7B is an exemplary depiction of the side view of the wafer after the disposing of the oxide pillar/strap on the wafer;

FIG. 8 is an exemplary depiction of the side view of the wafer after a lateral etch is performed through the STI trench to remove the entire BOX layer;

FIG. 9 is an exemplary depiction of the side view of the wafer after the disposing of the conformal oxide on the wafer;

FIG. 10 is an exemplary depiction of the side view of the wafer after the planarization;

FIG. 11A is an exemplary depiction of the side view of the wafer after the disposing of the photoresist RIE mask on the surface of the conformal oxide;

FIG. 11B is an exemplary depiction of the top view of the wafer after the disposing of the photoresist RIE mask on the surface of the conformal oxide;

FIG. 12 is an exemplary depiction of the top view of the wafer after the reactive ion etching;

FIG. 13A is an exemplary depiction of the top view of the wafer after the disposing of gate electrodes across a fin and across a planar oxide layer respectively;

FIG. 13B is an exemplary depiction of a cross-section of the planar MOSFET taken at section BB′; and

FIG. 13C is an exemplary depiction of a cross-section of the fin taken at section CC′.

### DETAILED DESCRIPTION

It will be understood that when an element or layer is referred to as being “on,” “interposed,” “disposed,” or “between” another element or layer, it can be directly on, interposed, disposed, or between the other element or layer or intervening elements or layers may be present.

It will be understood that, although the terms first, second, third, and the like may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, first element, component, region, layer or section discussed below could be termed second element, component, region, layer or section without departing from the teachings of the present invention.

As used herein, the singular forms “a,” “an” and “the” are intended to comprise the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Disclosed herein too is a structure for a double-gated finFET device that comprises a vertical fin and self-aligned gates “wrapped around” or over both sides and the top of the vertical fin. In one embodiment, the double-gated finFET device comprises a plurality of vertical fins disposed on a bulk silicon wafer (substrate). In another embodiment, the finFET device comprises a plurality of vertical fins disposed on a silicon on insulator (SOI) region of the substrate while a planar metal oxide semiconductor field effect transistor (MOSFET) is disposed on an adjacent bulk region of the substrate.

The thin vertical fins can produce “thin-body” effects, e.g., enhanced mobility and volume inversion. The “wrap around gate” places a gate so that it completely or almost-completely surrounds at least a portion of the fin or channel and thus, provides excellent gate control for turn-off and turn-on performance with the known advantages of “thin-body” effects. The multi-gated finFET device disclosed herein can be produced inexpensively because of the low substrate cost that comes from using a silicon wafer as the substrate, if desired.

In an exemplary embodiment, the finFET device comprises a first fin having a first gate electrode disposed across the first fin; the gate electrode contacting opposing surfaces of the fin; and a planar oxide layer having a second gate electrode disposed across the planar oxide layer to form a planar metal oxide semiconductor field effect transistor; the first fin and the planar oxide layer being disposed upon a surface of a wafer. In another exemplary embodiment, the finFET device comprises a plurality of fins, each fin having a gate electrode contacting opposing surfaces of the fin, the respective fins being disposed substantially parallel to one another on the surface of the wafer.

Disclosed herein too is a method for forming a double-gated finFET device that improves device uniformity. The method facilitates the formation of fins on bulk semiconductor wafers with improved fin height control. Additionally, the method provides the ability to form fins from bulk semiconductor while providing isolation between fins and between the source and drain regions of individual fins. The method advantageously provides for the optimization of fin height and width. The device structure also provides advantages of uniform finFET fabrication on bulk wafers.

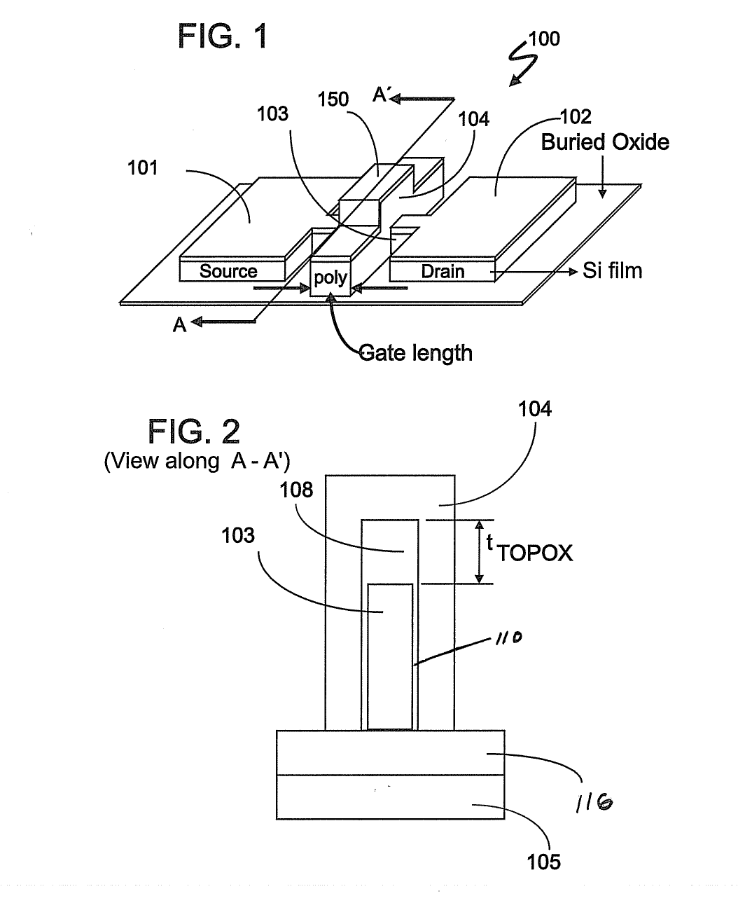

FIG. 1 depicts an exemplary perspective view of a finFET device 100 that comprises a single fin 103. It is to be recognized that while the FIG. 1 depicts a single fin 103, the finFET device may comprise a plurality of fins of different heights and thicknesses that are manufactured via an improved process that is disclosed herein and that facilitates the minimization of defects such as the “short channel effect”. The finFET device 100 comprises a source region 101, a drain region 102, a gate 104 and a fin 103 103. The portion of the fin 103 that is under gate 104 is the channel for the finFET device 100. An optional oxide layer 150 may be disposed upon the entire surface of the finFET device.

FIG. 2 depicts a view taken along the section AA′ of the FIG. 1 (without the optional oxide layer 150). With reference now to the FIG. 2, the fin FET device 100 comprises a wafer 105 having an epitaxially deposited silicon (EPI) layer 106 disposed thereon. The fin 103 is disposed on the SOI region of the wafer and has disposed upon it the oxide layer 116. The pad oxide layer 108 is disposed upon the fin 103 and is referred to as a gate oxide layer. A gate 104 is then disposed upon the gate oxide layer 108 to form the finFET device 100.

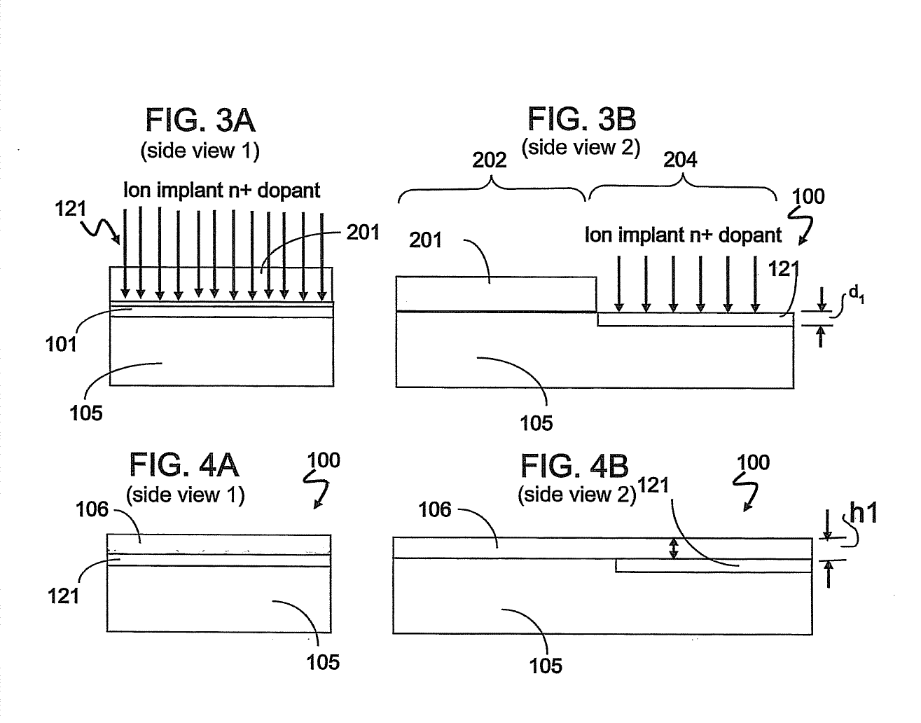

FIGS. 3A-13C will now be used to depict an exemplary method of manufacturing the finFET device 100. With respect to the FIGS. 3A and 3B, a wafer 105 having a first region 202 and a second region 204 is used as a substrate upon which to dispose the fins (not shown). FIG. 3A represents an end-on side view (represented as side view 1), while the FIG. 3B represents a second side view (represented as side view 2) of the wafer 105 during the manufacturing process. As will be disclosed herein, the first region 202 forms the bulk region having the planar MOSFET disposed thereon, while the second region 204 forms the SOI region with a fin or a plurality of fins disposed thereon.

Wafer 105 may comprise germanium, silicon, or a combination of germanium and silicon such as silicon-germanium. In an exemplary embodiment, the wafer comprises silicon. The wafer 105 has a buried oxide (BOX) layer 121 disposed thereon. In one embodiment, the BOX layer 121 can comprise silicon dioxide produced by doping the silicon wafer 105 with oxygen as a dopant. An ion beam implantation process followed by high temperature annealing can be used to form a BOX layer 121. In another embodiment, the BOX layer 121 and the wafer 111 can be separately adhered to each other.

With reference now to the FIG. 3B, in one manner of modifying the BOX layer 121, the first region 202 of the wafer (e.g., a silicon substrate) 105 is coated with a photoresist mask 201 following which the second region 204 of the wafer 105 is subjected to an ion bombardment with an N+ dopant to create the modified BOX layer 121. The modified BOX layer 121 is created in order to differentiate this region from the surrounding bulk silicon of the silicon substrate 105 so that it can be removed during a subsequent lateral etch, as will be described later. The N+ dopants can comprise arsenic (As), phosphorus (P), antimony (Sb), or the like, or a combination comprising at least one of the foregoing dopants. The modified BOX layer 121 can comprise the N+ dopants in a concentration of about 1.0E¹⁸ to about 1.0E²¹ atoms/cm³. The BOX layer 121 may extend from the surface of the substrate 105 to a depth “d₁” of about 100 to about 1,000 Angstroms (Å).

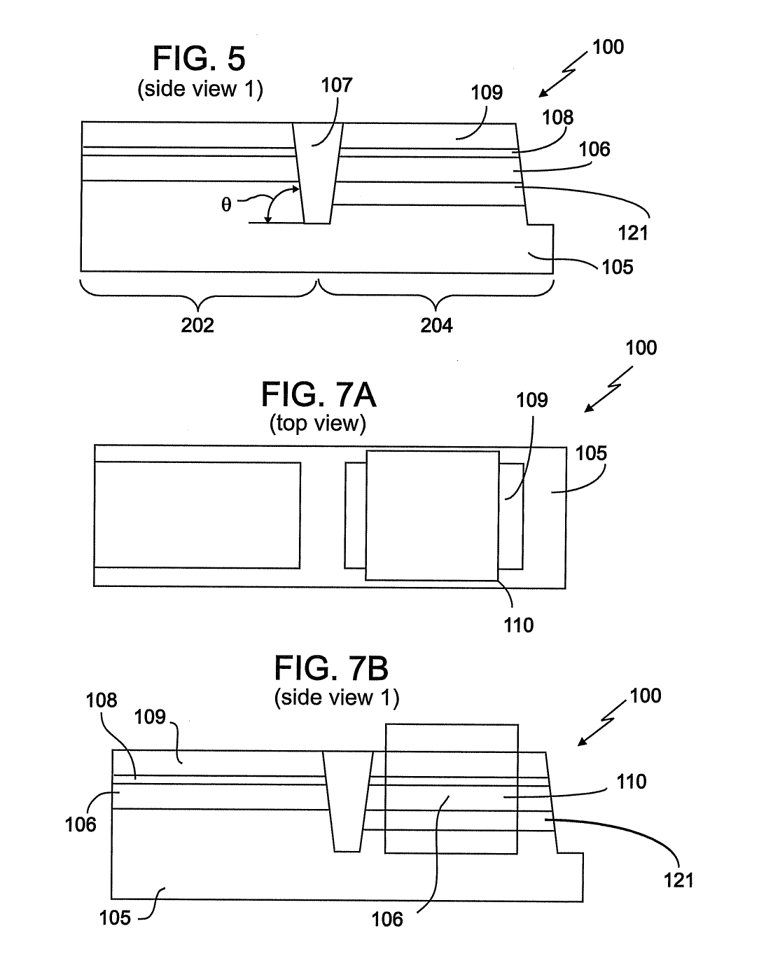

As shown in the FIGS. 4A and 4B, following the N-doping of the substrate 105, the photo resist implant mast 201 is removed, and an epitaxially deposited silicon (EPI) layer 106 is disposed across the entire surface of the silicon substrate 105 to cover both the first region 202 and the second region 204. FIG. 4A represents an end-on side view (represented as side view 1), while the FIG. 4B represents a second side view (represented as side view 2) of the wafer 105 after the deposition of the EPI layer 106. Side view 2 is 90 degrees to side view 1. The EPI layer 106 can be grown using vapor-phase epitaxy (VPE), a modification of chemical vapor deposition. Molecular-beam and liquid-phase epitaxy (MBE and LPE) may also used. An exemplary method of disposing the EPI layer 106 is chemical vapor deposition (vapor phase epitaxy).

The thickness of the EPI layer 106 determines the height of the fins. It is desirable for the EPI layer 106 to have a thickness of about 200 to about 1000 Å. A preferred thickness for the EPI layer 106 is about 500 Å. One of the advantages of this method of manufacturing a finFET device 100 is that since the thickness of the EPI layer 106 can be independently controlled, the height of the fins can be well controlled as well. This allows for a number of advantages such as ease of manufacturing, a reduction in manufacturing costs, an improvement in reproducibility and a reduction in the number of defects due to dimensional variability.

Following the deposition of the EPI layer 106, shallow isolation (STI) trenches are generated in the device 100 via an etching process. As can be seen in the FIG. 5, the STI trench 107 is etched through the EPI layer 106 and the bulk layer 105. Prior to the generation of the STI trench(es) 107, an optional pad oxide layer 108 and a silicon nitride layer 109 are respectively sequentially disposed upon the EPI layer 106. The silicon nitride layer 109 acts as a mask during the etching of the STI trench(es) 107. Etching may be conducted by any number of well known plasma etch processes or wet etch processes. In one embodiment, a reactive ion etching (RIE) with a halogenated compound such as CHF₃, Cl₂, CF₄ or SF₆ may be used to form the STI trenches 107 depicted in the FIG. 5. STI trench 107 can be defined with tapered sides having an angle θ of about 80 to about 88 degrees via use of a RIE pressure of about 4 to about 200 millitorr (mtorr). In another embodiment, a shallow trench 107 can also be formed with straight sides using an anisotropic RIE procedure at an RIE pressure of about 4 to about 200 mtorr.

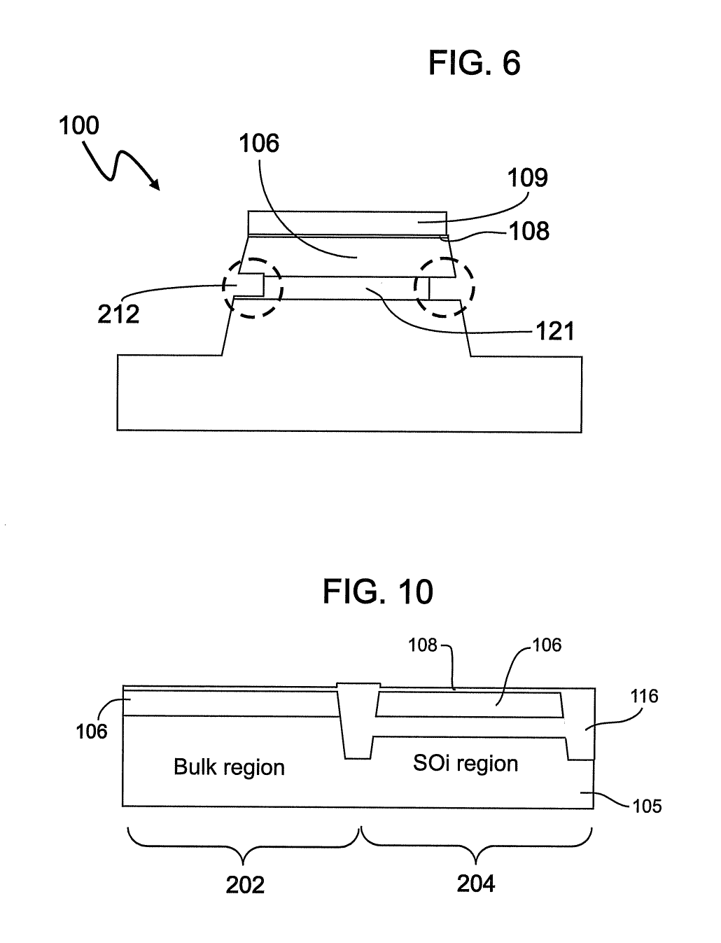

Following the formation of the STI trench(es) 107, a short lateral RIE is performed to remove a portion of modified BOX layer 121 at the sides of the second region 205 as depicted in the FIG. 6. The portion of the modified BOX layer 121 that is removed is depicted by the regions 212. The removal of the regions 212 of the modified BOX layer 121 creates the space for an oxide strap/pillar 110 (not shown) that after being deposited can support the weight of the EPI layer 106 above it (after the manufacturing of the STI trench 107).

As depicted in the FIGS. 7A and 7B, the oxide strap/pillar 110 sits upon the wafer 105 (in the second region 204) and is disposed in a manner such that it effectively wraps around and is in intimate contact with the portion of the device 100 that lies above the BOX layer 121 (i.e., the EPI layer 106, the pad oxide layer 108 and the silicon nitride layer 109). The oxide strap/pillar 110 can be disposed upon the second region 204 by processes such as low pressure chemical vapor deposition (LPCVD), plasma enhanced chemical vapor deposition (PECVD), expanding thermal plasma (ETP), ion plating, metal organic chemical vapor deposition (MOCVD) (also called organometallic chemical vapor deposition (OMCVD)), metal organic vapor phase epitaxy (MOVPE), physical vapor deposition processes such as sputtering, reactive electron beam (e-beam) deposition, and plasma spray. Exemplary processes are LPCVD and PECVD.

It is desirable for the oxide strap/pillar 110 to fill in the regions 212 created by the removal of the portion of the modified BOX layer 121. In filling the regions 212 created by the removal of the portion of the BOX layer 121, the oxide strap/pillar 110 creates mechanical support as well as facilitates maintaining alignment of the silicon layer disposed upon the modified BOX layer 121.

The oxide strap/pillar 110 generally comprises silicon dioxide, but other oxides such as alumina, titania, zirconia, ceria, or the like, or combination comprising at least one of the foregoing oxides may be used if different strain characteristics are desirable in the EPI layer 106.

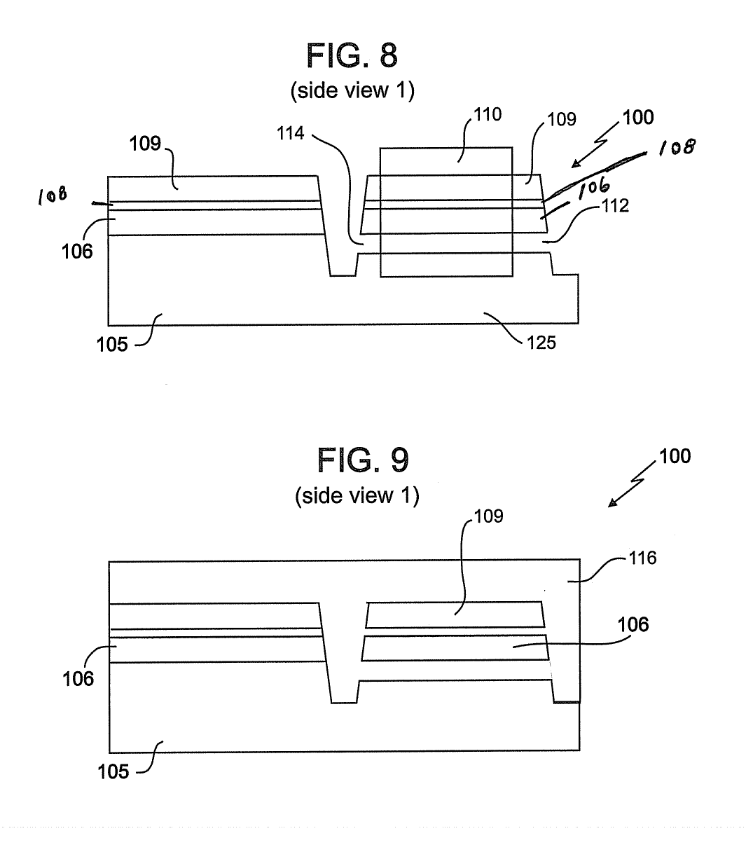

As depicted in the FIG. 8, following the deposition of the oxide strap/pillar 110, a lateral etch is performed via the STI trenches 107 to remove the entire modified BOX layer 121. The lateral etch is generally performed using a technique that is sensitive enough to differentiate between the material used for the wafer 105 and the BOX layer 121. In other words, the lateral etch removes material from the modified BOX layer 121 while minimally disturbing the material of the wafer 105. Exemplary techniques for performing the lateral etch are a wet chemical etch or a plasma etch. In one embodiment, a dry process using halogen based gases such as chlorine or bromine are used to remove the modified BOX layer 121. Possible wet etch solutions are ammonium hydroxide (NH₄OH).

When the modified BOX layer 121 is removed, an empty space is created between the wafer 105 and the EPI layer 106. The weight of the EPI layer 106 is supported by the oxide strap/pillar 110. As can be seen in the FIG. 8, the opposing end regions 114 (of the empty space 112) generally have a greater cross-sectional area than the cross-sectional area of the empty space 112. The greater cross-sectional area of the end regions 114 occurs because of the greater concentration of the etchant received by the end regions 114 as compared with the concentration of etchant received by the remainder of the empty space 112. The cross-sectional area of the end regions 114 is generally greater than the cross-sectional area of empty space 112 by an amount of up to about 110%, specifically up to about 120%, more specifically up to about 150% and even more specifically up to about 200%. It is to be noted that the respective cross-sectional areas are measured perpendicular to the base surface 125 of the wafer as shown in the FIG. 8.

Following the lateral etching to remove the N-doped region, a conformal oxide layer 116 is applied to the device as depicted in the FIG. 9. As can be seen in the FIG. 9, the conformal oxide layer 116 is applied to fill the empty space 112 and to surround the pad oxide layer 108, the silicon nitride layer 109 and the oxide strap/pillar 110. The conformal oxide layer 115 generally comprises silicon dioxide and is deposited using techniques such as PECVD or LPCVD.

Following the deposition of the conformal oxide layer, the conformal oxide layer is subjected to planarization to remove portions of the conformal oxide layer 116 that are disposed upon the silicon nitride layer 109 along with the silicon nitride layer 109. Planarization is conducted until the pad oxide layer 108 is exposed as can be seen in the FIG. 10. The planarization may comprise mechanical planarization, chemical planarization, chemical-mechanical planarization, or a combination comprising at least one of the foregoing forms of planarization. The height of the pad oxide 108 is about 20 to about 100 Å. The height of the pad oxide generally determines the thickness of the top oxide layer 108 (TOPOX) that is disposed upon the fin 103.

Following the planarization, a photoresist RIE mask 118 is disposed upon the exposed pad oxide layer 108 and a RIE process is performed to remove portions of the pad oxide layer 108 and the EPI layer 106. The photoresist RIE mask 118 is applied to facilitate the formation of the fins on the SOI region of the wafer and to facilitate the formation of a planar oxide layer on the bulk region of the wafer. The size of the photoresist RIE mask 118 determines the width of the fins and the width of the gate oxide layer. The width of the fins is about 10 to about 500 Å. A preferred width for the fins is about 100 Å. In one embodiment, the surface area of one of the photoresist RIE masks 118 disposed on the second region is equal to about the cross-sectional area of at least one fin.

Following the deposition of the photoresist RIE mask 118 on the pad oxide layer 108, a RIE process using a halogenated compound such as CHF₃, Cl₂, CF₄ or SF₆ may be used to remove the regions that are not protected by the photoresist RIE mask 118. Portions of the pad oxide layer 108 and the EPI layer 106 thus are removed by RIE to create the fin 103 with the top oxide layer 108 disposed thereon as depicted in the FIG. 2.

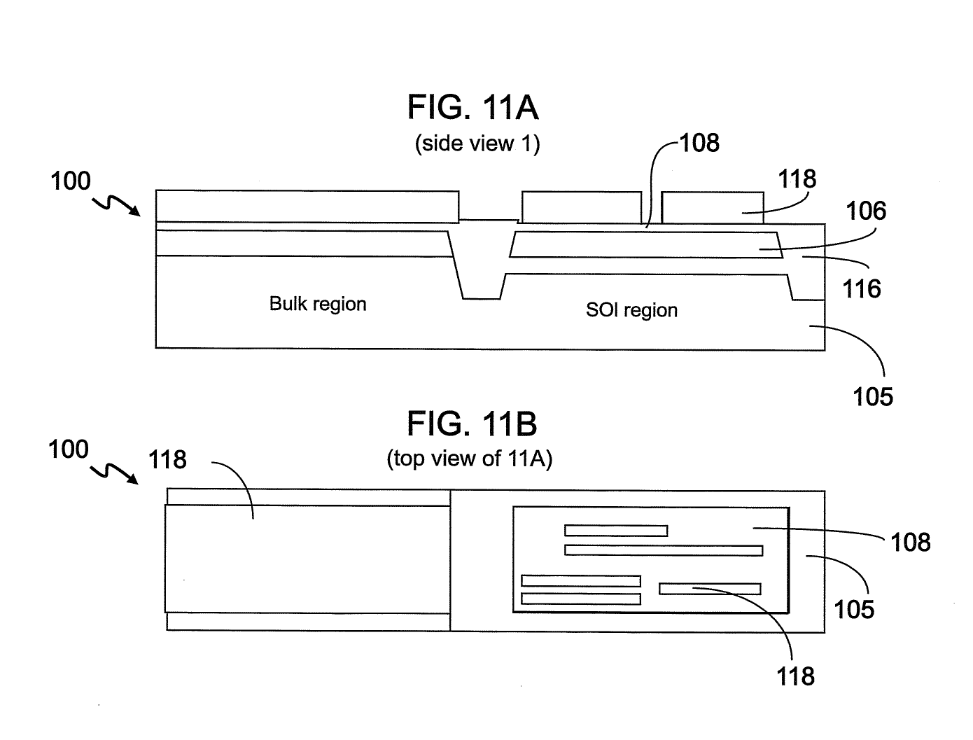

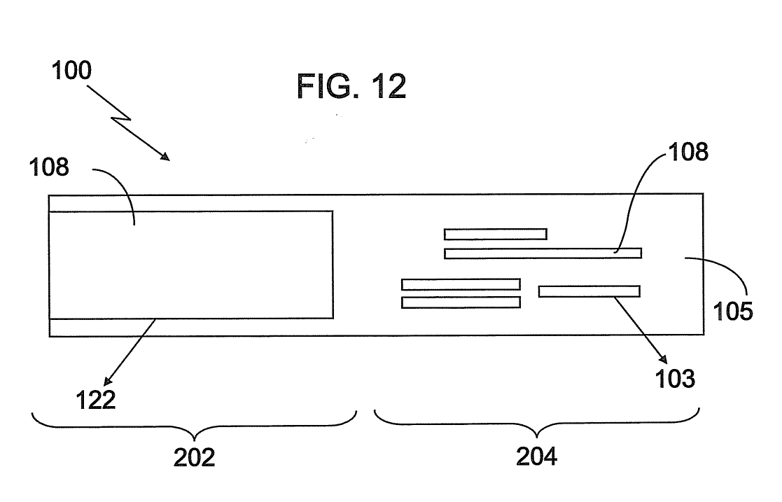

The process is depicted in the FIGS. 11-12. FIGS. 11A and 11B respectively depict the side view and top view respectively of the RIE mask 118 disposed upon the pad oxide layer. FIG. 12 depicts the plurality of fins formed in the second region 204 (SOI region) and the planar oxide layer 122 formed in the first region 202 (bulk region). The planar oxide layer 122 is formed in the first region 202 since no patterning is conducted to produce the fins that are produced in the second region 204.

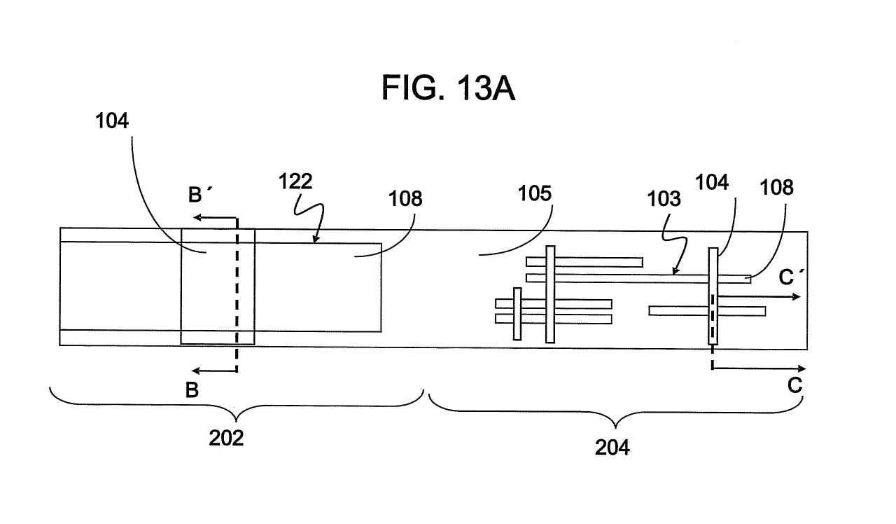

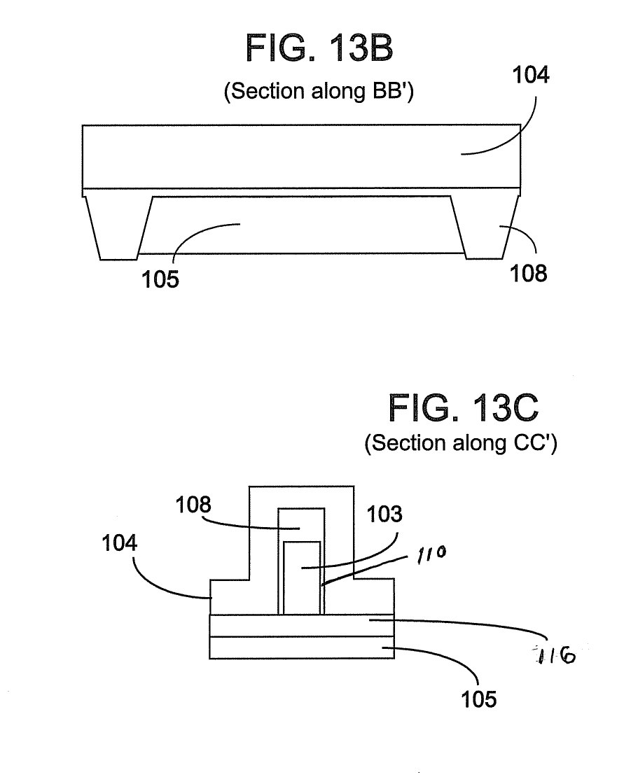

FIGS. 13A, 13B and 13C depict the formation of the planar MOSFET layer and the finFETs after the deposition of the gate electrode. The gate electrode 104 may be manufactured by using one of gate materials such as polysilicon (P+or N+ doping), SiGe (P+or N+ doping), or metals. The gate dimensions can be defined by using photolithography. As can be seen in the FIG. 13A, a first fin 103 has disposed across its opposing faces a first gate electrode 104, while at the same time a planar oxide layer 122 has disposed across it surface a second gate electrode. The FIG. 13A also depicts a plurality of fins disposed on the surface of the wafer. The plurality of fins are substantially parallel to each other, though this is not always desirable. Gate electrodes are disposed across the surface of the plurality of fins.

FIG. 13B is a cross sectional view of the finFET device 100 taken at section BB′ in the first region 202 of the FIG. 13A. The disposing of the gate electrode 104 across the planar oxide layer 122 produces a planar MOSFET device. Lateral dimensions for the planar device is a circuit design parameter that can range from about 100 nanometers up to about 100 micrometers.

FIG. 13C is a cross-sectional view of the wafer 105 taken at section CC′ in the second region 204 of the FIG. 13A respectively. As can be seen in the FIG. 13C, the fin 103 has a height equal to that of the EPI layer 106 disposed early in the manufacturing process. The disposing of the gate electrode 104 across the fins 103 results in the formation of the finFET device 100.

This method of manufacturing the fins 103 provides some unique advantages. It provides better control over structure parameters when compared with other available commercially available processes. The method of depositing an EPI layer 106 early in the process provides better reproducibility of fin height and width. There is also a reduction in substrate cost since the method advantageously permits the use of a silicon substrate (wafer). It can be used in circuits where aggressive gate scaling (Lg) is not desirable. It can also however be used in devices where aggressive gate scaling is desired. For example, the method advantageously permits the manufacturing of multigate devices or double gate devices with gate lengths of less than about 30 nanometers.

Circuits that require contact with the bulk can remain in contact with bulk silicon, while those circuits that require unique functionality can remain in contact with either the bulk silicon or with an SOI layer.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

1. A method of forming a semiconductor device on a bulk substrate having a first region and a second region, the method comprising:
forming a sacrificial buried oxide (BOX) layer on only the second region of the bulk substrate;
forming an epitaxially deposited silicon layer on the sacrificial BOX layer in the second region as well as on the first region of the bulk substrate, at a thickness corresponding to a desired height of a finFET fin;
forming a pad oxide layer and a silicon nitride mask on the epitaxially deposited silicon layer; the pad oxide layer being disposed beneath the silicon nitride mask;
etching a shallow trench in the silicon nitride mask, the pad oxide layer, the epitaxially deposited silicon layer and the bulk substrate;
performing a lateral etch so as to remove a portion of the sacrificial BOX layer and creating an empty space adjacent a side of the sacrificial BOX layer;
forming an oxide strap over the first region of the bulk substrate so as to encompass the silicon nitride mask; a portion of the oxide strap filling the empty space created adjacent the sacrificial BOX layer;
completely removing the sacrificial BOX layer;
disposing a conformal oxide over the first and second regions of the bulk substrate, the conformal oxide filling portions vacated by completely removing the sacrificial BOX layer;
planarizing the conformal oxide to expose a surface of the pad oxide layer;
forming a photoresist layer over the first and second regions of the bulk substrate;
patterning the photoresist layer and etching exposed portions of the pad oxide layer and then etching exposed portions of the epitaxially deposited silicon layer in the second region so as to create one or more fins only in the second region of the bulk substrate; and
forming and patterning a gate conductor material over the first and second regions so as to form one or more planar field effect transistor (FET) devices in the first region and one or more finFET devices in the second region.

2. The method of claim 1, wherein the etching of the shallow trench is conducted using a reactive ion etching.

3. (canceled)

4. The method of claim 1, wherein the oxide strap contacts the sacrificial BOX layer in a region that is disposed between the bulk substrate and the epitaxially deposited silicon layer.

5. The method of claim 1, wherein the oxide strap supports the weight of the epitaxially deposited silicon layer and facilitates in aligning the fin.

6-12. (canceled)

13. The method of claim 1, wherein the empty space adjacent the sacrificial BOX layer includes end regions that have a larger cross-sectional area than a cross-sectional area of the empty space, the respective cross-sectional areas being measured perpendicular to a base surface of the bulk substrate.

14. An article formed by the method of claim 1.

15-22. (canceled)

23. An article formed by the method of claim 13.
